(19) United States
(12) Patent Application Publication
(10) Pub. No.: US 2002/0075038 A1
(43) Pub. Date: Jun. 20, 2002

(54) Active leakage control technique for high performance dynamic circuits

(75) Inventors: Sanu K. Mathew, Hillsboro, OR (US); Ram K. Krishnamurthy, Beaverton, OR (US)

Correspondence Address: Schwegman, Lundberg, Woessner & Kluth, P.A., P.O. Box 2938, Minneapolis, MN, 55402, US

(73) Assignee: Intel Corporation

(21) Appl. No.: 09/741,367

(22) Filed: Dec. 19, 2000

(51) Int. Cl. H03K 19/096

(52) U.S. Cl. 326/95

(57) ABSTRACT

A dynamic logic gate receives a bias voltage at a data input terminal thereof that is designed to reduce leakage current within the gate. This reduction in leakage current improves the robustness of the dynamic logic gate without requiring the use of performance reducing high threshold voltage transistors within the gate. In one embodiment, the bias voltage is generated using a bootstrap capacitor that is connected to a virtual ground node of a static inverter in a domino logic chain. The bootstrap capacitor causes a small negative voltage to be applied to the virtual ground node in response to a clock signal. Under certain data conditions, the small negative voltage will be coupled to the input terminal of a subsequent dynamic logic gate in the logic chain to reduce leakage current within the subsequent gate.

### FIELD OF THE INVENTION

The invention relates generally to semiconductor logic circuits and, more particularly, to techniques and structures for controlling leakage therein.

### BACKGROUND OF THE INVENTION

An ongoing trend in the integrated circuit (IC) industry is to continuously reduce the physical size of ICs. This reduction in size is often achieved by device scaling where each of the dimensions of a circuit are reduced by a predetermined amount to create a smaller circuit having the same or similar operating characteristics as the original circuit. Device scaling, however, has resulted in an increase in sub-threshold leakage currents within circuits using field effect transistors, particularly insulated gate field effect transistors (IGFETs) (e.g., metal-oxide-semiconductor field effect transistors (MOSFETs)). This increased leakage can have a negative impact on circuit robustness, particularly in circuits utilizing high fan-in dynamic gate structures. One technique for improving the robustness of such circuits is to utilize higher threshold voltage (V_{T}) transistors within the IC that are less likely to leak when the transistors are in an “off” condition. The use of high V_{T} transistors, however, will often cause a significant reduction in performance in an IC. As can be appreciated, such performance penalties are generally undesirable.

### BRIEF DESCRIPTION OF THE DRAWINGS

FIG. 1 is a schematic diagram illustrating a dynamic logic circuit in accordance with one embodiment of the present invention; and

FIG. 2 is a timing diagram illustrating the operation of the dynamic logic circuit of FIG. 1 in one embodiment of the present invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention relates to structures and techniques for controlling transistor leakage within high performance dynamic logic circuits. A bias voltage is applied to a data input of a dynamic logic gate at an appropriate time during circuit operation to reduce leakage current within the gate that could otherwise compromise the integrity of the output data of the gate. This reduction in leakage current enhances the robustness of the dynamic logic gate without requiring the use of high threshold voltage (V_{T}) transistors within the gate (although, in at least one embodiment, high V_{T} devices are used within the gate). Thus, the circuit robustness typically associated with high V_{T} transistors can be achieved at a performance level characteristic of low V_{T} devices. The inventive principles are capable of implementation within a wide variety of different logic circuits that utilize dynamic logic techniques. In at least one embodiment, the inventive principles are implemented in a logic circuit utilizing dual-V_{T} techniques. In another embodiment, the inventive principles are used as an iso-robustness, high performance technique to replace high V_{T} devices in a dual-V_{T} dynamic circuit. The inventive principles are capable of implementation within already existing dynamic logic chains without requiring any change in the timing plan or clocking methodology. In addition, the inventive principles can be used as an active leakage control technique to reduce active leakage power consumption. The inventive principles are particularly beneficial when used in dynamic logic gates that are prone to leakage related problems, such as the high fan-in dynamic NOR gates commonly used in schedulers and register files.

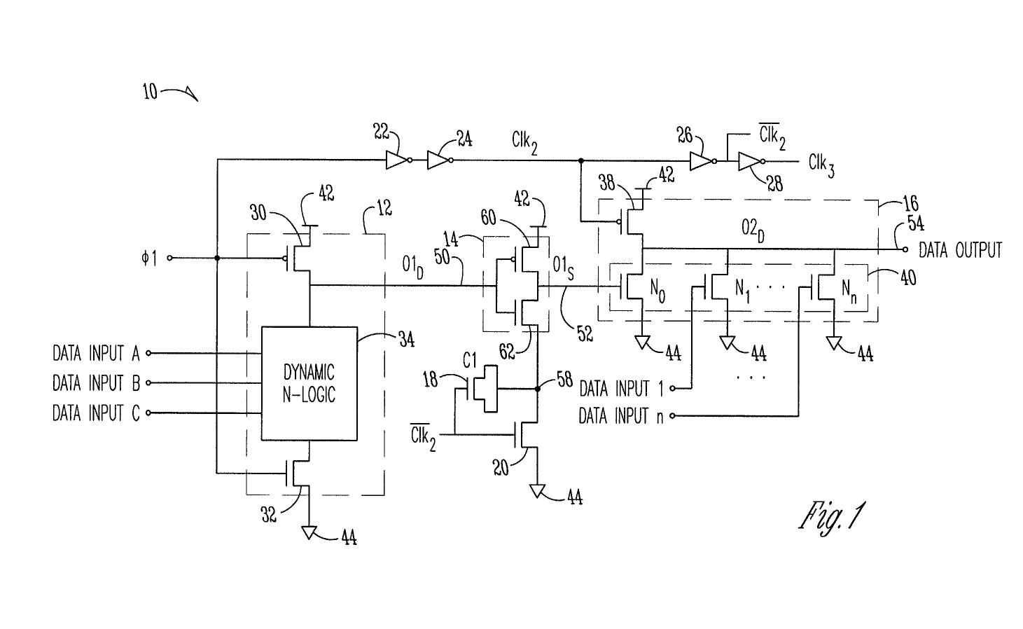

FIG. 1 is a schematic diagram illustrating a dynamic logic circuit 10 in accordance with one embodiment of the present invention. The dynamic logic circuit 10 forms a portion of a larger logic circuit that executes one or more predetermined logic functions within a digital processing device (e.g., a microprocessor). As illustrated, the dynamic logic circuit 10 includes: a first dynamic logic gate 12, a static inverter 14, a second dynamic logic gate 16, a bootstrap capacitor 18, a ground transistor 20, and a plurality of clock inverters 22, 24, 26, 28. The first dynamic logic gate 12 processes a number of data input signals to generate, in a dynamic manner, a logic value on a first dynamic output node 50 (i.e., node O1_{D}). The static inverter 14 inverts the logic value on the first dynamic output node 50 to generate a complementary logic value on a static output node 52 (i.e., node O1_{S}) of the inverter 14. The complementary logic value is then input to the second dynamic logic gate 16 which uses the input value (as well as logic values received at other data inputs) to generate a logic value on a second dynamic output node 54 (i.e., node O2_{D}). Further dynamic logic gates can be cascaded after the second dynamic logic gate 16 if additional logical processing is required. The plurality of clock inverters 22,24, 26, 28 are operative for distributing an input clock signal φ₁ through the logic chain. The bootstrap capacitor 18 and the ground transistor 20 are operative for generating a properly timed bias voltage that reduces leakage within the second dynamic logic gate 16 during appropriate periods to increase the robustness of the dynamic logic circuit 10.

As illustrated in FIG. 1, the first dynamic logic gate 12 includes: a first precharge transistor 30, an evaluation transistor 32, and a first dynamic N-logic block 34. The first precharge transistor 30 is connected between a supply terminal 42 and the dynamic N-logic block 34. The first dynamic output node 50 occurs between the first precharge transistor 30 and the dynamic N-logic block 34. The evaluation transistor 32 is connected between the dynamic N-logic block 34 and a ground terminal 44. The gate terminals of the first precharge transistor 30 and the evaluation transistor 32 each receive an input clock signal φ₁. In a preferred approach, the input clock signal l approximates a square wave having alternating high and low voltage portions. In the illustrated embodiment, the first precharge transistor 30 is a PMOS transistor and the evaluation transistor 32 is an NMOS transistor. Therefore, during a “low” portion of the input clock signal φ₁, the first precharge transistor 30 connects the first dynamic node 50 to the supply terminal 42, which precharges the first dynamic node 50 to the supply potential (e.g., V_{DD}). This interval will be referred to herein as the “precharge period” of the first dynamic logic gate 12.

During a “high” portion of the input clock signal φ₁, the first precharge transistor 30 is turned “off” and the evaluation transistor 32 is turned “on,” thus connecting the dynamic N-logic block 34 to the ground terminal 44 (e.g., V_{SS}). This interval will be referred to herein as the “evaluation period” of the first dynamic logic gate 12. During this evaluation period, the dynamic N-logic block 34 will conditionally discharge the first dynamic node 50 based on input data at one or more data inputs (e.g., DATA INPUT A, DATA INPUT B, and DATA INPUT C in the illustrated embodiment) of the N-logic block 34. The dynamic N-logic block 34 will typically include one or more NMOS transistors arranged to achieve a predetermined logic function within the block 34. This logic function will cause the dynamic N-logic block 34 to create a short circuit between the first dynamic output node 50 and the evaluation transistor 32 when the input data meets a predetermined logical criterion. Because the evaluation transistor 32 is conducting during the evaluation period, the first dynamic node 50 will be discharged to ground during the evaluation period when the predetermined criterion is met. Note that the evaluation transistor 32 can be omitted if the inputs of the dynamic N-logic block 34 are guaranteed to be zero during the precharge period.

As illustrated in FIG. 1, the static inverter 14 includes a PMOS transistor 60 and an NMOS transistor 62. The output terminals of the PMOS transistor 60 are connected to the supply terminal 42 and the static output node 52, respectively. The output terminals of the NMOS transistor 62 are connected to the static output node 52 and a virtual ground node 58, respectively. The gate terminals of the PMOS transistor 60 and the NMOS transistor 62 are each connected to the first dynamic output node 50 of the first dynamic logic gate 12. When the first dynamic output node 50 is carrying a logic low value (e.g., when the node 50 has been discharged), the NMOS transistor 62 is turned off and the PMOS transistor 60 is turned on. Thus, the static output node 52 is connected to the supply terminal 42 and a logic high value appears on the static output node 52. When the first dynamic output node 50 is carrying a logic high value (e.g., when the node 50 is precharged), the PMOS transistor 60 is turned off and the NMOS transistor 62 is turned on. Thus, the static output node 52 is connected to the virtual ground node 58 and a logic low value appears on the static output node 52. As will be described in greater detail, the bootstrap capacitor 18 and the ground transistor 20 are operative for changing the voltage on the virtual ground node 58 at predetermined times during circuit operation to conditionally modify a voltage on the static output node 52 in a manner that reduces leakage within the second dynamic logic gate 16.

The second dynamic logic gate 16 includes a second precharge transistor 38 and a second dynamic N-logic block 40. In a similar manner to the first precharge transistor 30, the second precharge transistor 38 precharges the second dynamic output node 54 based on an input clock signal (i.e., CLK₂) applied to the gate terminal thereof. As illustrated, the CLK₂ signal applied to the second precharge transistor 38 is derived from the original clock signal φ₁ using two clock inverters 22, 24. These clock inverters 22, 24 serve to add a small time delay to the original clock signal φ₁, while also boosting the magnitude of the original clock signal φ₁ to compensate for any signal attenuation that may have taken place within the clock line. The low portion of the CLK₂ signal defines the precharge period of the second dynamic logic gate 16 and the high portion of the CLK₂ signal defines the evaluation period of the second dynamic logic gate 16. During the evaluation period of the second dynamic logic gate 16, the second dynamic N-logic block 40 conditionally discharges the second dynamic output node 54 based on the voltage value on the static output node 52 of the inverter 14 during the evaluation. As illustrated, the second dynamic N-logic block 40 may also receive data inputs (e.g., data input 1 and data input n) from dynamic logic gates other than the first dynamic logic gate 12 (which will also typically include an intervening static inverter). After the evaluation operation has been performed, the logic value on the second dynamic output node 54 of the second dynamic logic gate 16 can be delivered to, for example, another dynamic logic gate in the chain via another static inverter. A logic chain of this type is typically referred to as “domino logic” because of the manner in which the evaluated logic values propagate through the chain.

In the illustrated embodiment, the second dynamic N-logic block 40 is a dynamic NOR gate. That is, the second dynamic N-logic block 40 includes a plurality of NMOS transistors (N₀, N₁, . . . , N_{N}) that are each connected between the second dynamic output node 54 and the ground terminal 44. The gate terminal of at least one of the NMOS transistors (e.g., N₀) within the second dynamic N-logic block 40 is connected to the static output node 52 of the static inverter 14. The gate terminals of other NMOS transistors (e.g., N₁ and N_{N}) within the second dynamic N-logic block 40 are connected to static inverter output nodes associated with other dynamic logic gates. If a logic high value is present on the gate terminal of any of the NMOS transistors (i.e., N₀,N₁, . . . , N_{N}) within the second dynamic N-logic block 40 during an evaluation, that transistor will be turned on and the second dynamic output node 54 will be discharged to ground. Thus, the second dynamic N-logic block 40 implements the well known NOR logic function. As described previously, the NMOS transistors (N₀, N₁, . . . , N_{N}) within the second dynamic N-logic block 40 may experience some sub-threshold leakage during normal operating conditions. This sub-threshold leakage will act to discharge the second dynamic output node 54 during an evaluation period even when none of the NMOS transistors (N₀, N₁, . . . , N_{N}) are receiving a logic high value on a corresponding gate terminal. If the rate of the leakage related discharge is high enough, the voltage on the second dynamic output node 54 can be incorrectly reduced to a logic low value before the end of the evaluation period, thus introducing an error into the logic function. As can be appreciated, the greater the number of NMOS transistors between the second dynamic output node 54 and the ground terminal 44, the greater will be the cumulative leakage. For this reason, wide high fan-in dynamic gates typically present the greatest leakage risks. A gate that has four inputs or greater is typically considered a wide high fan-in gate.

In conceiving the present invention, it was appreciated that the leakage current through a FET device could be controlled to some extent by appropriately biasing the device. For example, in one process it was discovered that sub-threshold leakage within a low V_{T} NMOS transistor could be reduced by a factor of five by under-driving the gate of the transistor by only −65 millivolts (mV). Therefore, in accordance with one aspect of the present invention, a bias voltage is applied to a data input of a dynamic logic gate during an appropriate operational period to reduce leakage through the dynamic logic gate. The bias voltage is typically different from the voltages representative of logic values within the circuit (e.g., V_{DD} and V_{SS}). As discussed above, the bootstrap capacitor 18 and the ground transistor 20 illustrated in FIG. 1 represent one form of bias circuit that can be used for applying such a bias voltage. As will be apparent to persons of ordinary skill in the art, other bias circuits for applying leakage reducing bias voltages to the data inputs of dynamic logic gates can also be used. This can include, for example, bias circuits connected directly to a data input terminal of a dynamic gate (i.e., not through an inverter).

As shown in FIG. 1, the ground transistor 20 is connected between the virtual ground node 58 and the ground terminal 44. The ground transistor 20 receives an input clock signal (CLK₂#) at a gate terminal thereof that is an inverted version of the CLK₂ signal delivered to the second precharge transistor 38. Therefore, except for a small time delay, the CLK₂# signal coincides with the precharge/evaluate cycle of the second dynamic logic gate 16. When the CLK₂# signal is logic high, the ground transistor 20 is turned on and the virtual ground node 58 is grounded. This period corresponds approximately to the precharge period of the second dynamic logic gate 16. When the CLK₂# signal is logic low, the ground transistor 20 is turned off and the virtual ground node 58 is isolated from the ground terminal 44. This period corresponds approximately to the evaluation period of the second dynamic logic gate 16.

The bootstrap capacitor 18 is connected between the line carrying the CLK₂# signal and the virtual ground node 58. In the illustrated embodiment, the bootstrap capacitor 18 is implemented using an NMOS transistor having its source and drain terminals shorted together. As will be appreciated by persons of ordinary skill in the art, other techniques for implementing the bootstrap capacitor 18 are also possible. As discussed above, when the CLK₂# signal is high, the virtual ground node 58 is grounded (i.e., at zero potential). Thus, the full voltage of the CLK₂# signal is across the bootstrap capacitor 18. When the CLK₂# signal subsequently transitions to a low value, the virtual ground node 58 is isolated from the ground terminal 44 and a negative voltage results on the virtual ground node 58 by, among other things, the coupling action of the bootstrap capacitor 18. Therefore, when the first dynamic output node 50 is carrying a logic high value and the CLK₂# signal is logic low, a small negative voltage is applied to the input of the second dynamic logic gate 16 to reduce leakage through a corresponding NMOS transistor (i.e., No). A similar small negative voltage is also preferably applied to each other data input of the second dynamic logic gate 16 that is to receive a logic low value. When the first dynamic output node 50 is carrying a logic low value (e.g., after the node 50 has been discharged), the NMOS transistor 62 of the static inverter 14 is turned off and the voltage on the virtual ground node 58 is isolated from the input of the second dynamic logic gate 16. The capacitance value of the bootstrap capacitor 18 is selected so that the capacitance divider that it forms with the diffusion capacitances of the static inverter transistors 60, 62 and the gate capacitance of transistor N₀ within the second dynamic logic gate 16 provides the desired small negative voltage on the virtual ground node 58 during the appropriate period. The magnitude of the small negative voltage will usually depend upon the particular transistor being used and the level of leakage reduction desired.

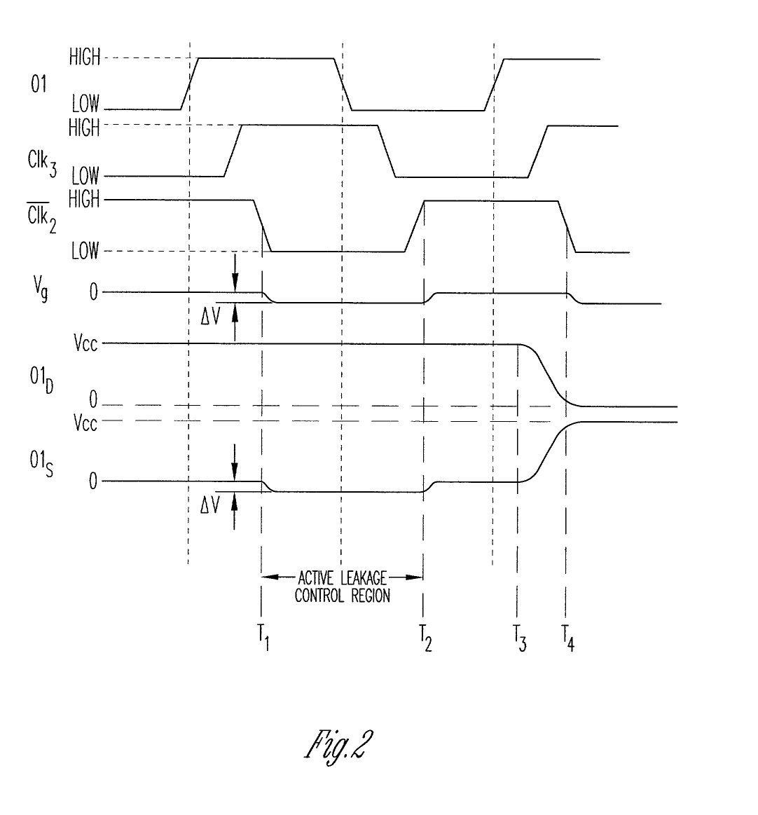

FIG. 2 is a timing diagram illustrating the operation of the dynamic logic circuit 10 of FIG. 1 in one embodiment of the present invention. As illustrated, the timing diagram of FIG. 2 includes voltage waveforms representing clock signals φ₁, CLK₂, and CLK₂# and the signals on the virtual ground node 58 (VG), the first dynamic output node 50 (O1_{D}), and the static output node 52 (O1_{S}). As illustrated, the φ₁ signal approximates a square wave that alternates between high and low voltage values (i.e., HIGH and LOW). The CLK₂ signal is a slightly delayed version of the φ₁ signal due to the inherent delay of the two clock inverters 22, 24. This delay is exaggerated in FIG. 2 for purposes of illustration. The CLK₂# signal is an inverted version of the CLK₂ signal that is also slightly delayed due to the inherent delay of clock inverter 26. As illustrated, when the CLK₂# signal is logic high, the virtual ground has a voltage of zero. At time T1, however, the CLK₂# signal begins to transition to a logic low value, which causes a small negative voltage (−ΔV) to develop on the virtual ground node 58. Because the voltage on the first dynamic output node 50(O1_{D}) is logic high at this time (i.e., the first dynamic output node 50 has not been discharged), the small negative voltage (−ΔV) on the virtual ground node 58 translates to the static output node 52 of the static inverter 14. As discussed previously, the presence of this voltage on the input terminal of the second dynamic logic gate 16 reduces leakage within the gate 16.

As shown, the small negative voltage (−ΔV) remains on the static output node 52 until the CLK₂# signal transitions back to a logic high value at time T₂ (corresponding approximately to the beginning of the precharge period in the second dynamic logic gate 16). Therefore, the small negative voltage (−ΔV) is present on the input terminal of the second dynamic logic gate 16 for a large portion of the evaluation period thereof. As can be appreciated, the longer the small negative voltage is present on the input terminal of the second dynamic logic gate 16 during the evaluation period, the greater is the reduction in leakage. Therefore, in at least one embodiment of the invention, this time period is maximized. It should be appreciated, however, that smaller time periods are also possible. Just after time T₂, the voltage on the virtual ground node 58 and the static output node 52 (O1_{S}) returns to zero. In this manner, the evaluation delay in one cycle will not be effected by the biasing operation in the previous cycle.

At time T₃, the first dynamic output node 50(O1_{D}) begins to discharge during an evaluation of the first dynamic logic gate 12. This causes the NMOS transistor 62 within the inverter 14 to turn off and PMOS transistor 60 to turn on (connecting the supply terminal 42 to the static output node 52). Subsequently, at time T₄, the CLK₂# signal again transitions to a low voltage value and, as before, a small negative voltage (−ΔV) develops on the virtual ground node 58. However, as illustrated, because the NMOS transistor 62 is off at this time, the voltage on the virtual ground node 58 has no effect on the static output node 52.

In the embodiment of FIG. 1, as described above, the second dynamic logic gate 16 includes an N-logic, high fan-in NOR gate to conditionally discharge a precharged dynamic node. It should be appreciated that the inventive principles can also be used to reduce leakage and improve robustness in other types of dynamic logic gates including, for example, dynamic gates that pre-discharge a corresponding dynamic node and dynamic gates that utilize P-logic. In addition, the inventive principles can be used in dynamic logic circuits other than domino-based logic chains. The inventive principles can be used with almost any wide dynamic gate that would otherwise require high-V_{T} devices to maintain robustness. The magnitude and polarity of the leakage-reducing bias voltage will generally depend upon the specific logic type being implemented. As described above, in at least one embodiment, the inventive principles are used in conjunction with dual-V_{T} techniques to further enhance the robustness of the dynamic nodes. For example, in one approach, high V_{T} devices are used within the wide dynamic gates of the system and the bootstrap circuitry is used to under drive the gates of these devices.

Although the present invention has been described in conjunction with certain embodiments, it is to be understood that modifications and variations may be resorted to without departing from the spirit and scope of the invention as those skilled in the art readily understand. Such modifications and variations are considered to be within the purview and scope of the invention and the appended claims.

What is claimed is:

1. A dynamic logic circuit comprising:
a dynamic logic gate including:
a dynamic output node;
a transistor to apply a first voltage level to said dynamic output node during a first time period; and
a logic block having a plurality of data inputs, said plurality of data inputs including a first data input, said logic block to conditionally modify a voltage level on said dynamic output node during a second time period based on voltage levels on said plurality of data inputs, said second time period occurring after said first time period; and
a bias circuit coupled to said first data input of said logic block to apply a bias voltage to said first data input when predetermined conditions exist to reduce leakage through said logic block.

2. The dynamic logic circuit claimed in claim 1, wherein:
said first time period is a precharge period of said dynamic logic gate during which said transistor precharges said dynamic output node to said first voltage level; and
said second time period is an evaluation period during which said logic block conditionally discharges said dynamic output node.

3. The dynamic logic circuit claimed in claim 1, wherein:
said first time period is a pre-discharge period of said dynamic logic gate during which said transistor pre-discharges said dynamic output node to said first voltage level; and
said second time period is an evaluation period during which said logic block conditionally charges said dynamic output node.

4. The dynamic logic circuit claimed in claim 1, wherein:
said bias circuit applies said bias voltage to said first data input during at least a portion of said second time period.

5. The dynamic logic circuit claimed in claim 4, wherein:
said bias circuit applies said bias voltage to said first data input of said logic block when a predetermined data value is to be applied to said first data input during said portion of said second time period.

6. The dynamic logic circuit claimed in claim 5, wherein:
said predetermined data value includes a logic low value.

7. The dynamic logic circuit claimed in claim 1, wherein:
said bias circuit includes a bootstrap capacitor connected to a virtual ground node of a static inverter feeding said first data input of said logic block.

8. The dynamic logic circuit claimed in claim 1, wherein:
said bias voltage is different from voltages representative of data values within said dynamic logic gate.

9. The dynamic logic circuit claimed in claim 1, wherein:
said logic block includes an NMOS transistor, said first data input of said logic block being connected to a gate terminal of said NMOS transistor, wherein said bias voltage includes a small negative voltage.

10. The dynamic logic circuit claimed in claim 1, wherein:
said logic block is a wide high fan-in logic structure.

11. A dynamic logic circuit comprising:
a first dynamic gate having a first dynamic output node;
a static inverter coupled to said first dynamic output node, said static inverter having a static output node and a virtual ground node, said static inverter to invert a data value on said first dynamic output node to generate a complement data value on said static output node;
a second dynamic gate coupled to said static output node, said second dynamic gate having a second dynamic output node, said second dynamic gate to conditionally modify a data value on said second dynamic output node based on a voltage level on said static output node during an evaluation period of said second dynamic gate; and
a bias circuit to cause a bias voltage to be applied to said static output node when a predetermined condition exists to reduce charge leakage within said second dynamic gate.

12. The dynamic logic circuit claimed in claim 11, wherein:
said bias circuit is coupled to said virtual ground node of said static inverter.

13. The dynamic logic circuit claimed in claim 12, wherein:
said bias circuit applies said bias voltage to said virtual ground node of said static inverter during said evaluation period of said second dynamic gate.

14. The dynamic logic circuit claimed in claim 13, wherein:
said static inverter couples said bias voltage applied to said virtual ground node by said bias circuit to said static output node when a logic high data value is present on said first dynamic output node.

15. The dynamic logic circuit claimed in claim 12, wherein:
said bias circuit includes a bootstrap capacitor connected to said virtual ground node of said static inverter , said bootstrap capacitor to generate, by bootstrapping action, a small negative bias voltage on said virtual ground node in response to a clock signal.

16. The dynamic logic circuit claimed in claim 15, wherein:
said bias circuit includes a ground transistor connected to said virtual ground node of said static inverter, said ground transistor to controllably couple said virtual ground node to a ground terminal in response to said clock signal.

17. The dynamic logic circuit claimed in claim 16, wherein:
said ground transistor receives said clock signal at an input terminal thereof, wherein said bootstrap capacitor is connected between said input terminal of said ground transistor and said virtual ground node.

18. The dynamic logic circuit claimed in claim 11, wherein:
said second dynamic gate includes a dynamic N-logic block and said bias voltage is a small negative voltage.

19. The dynamic logic circuit claimed in claim 11, wherein:
said second dynamic gate includes a wide high fan-in logic structure.

20. The dynamic logic circuit claimed in claim 11, wherein:
said bias voltage is different from voltages representative of data on said static output node.

21. A dynamic logic circuit comprising:
a first dynamic logic gate including:
a first precharge transistor to precharge a first dynamic node during a first precharge period; and
a first logic block to conditionally discharge said first dynamic node during a first evaluation period following said first precharge period based on input data received by said first logic block;
a static inverter coupled to said first dynamic node to invert a data bit value on said first dynamic node to generate a complement data bit value on a static output node of said static inverter, said static inverter having a virtual ground node;
a second dynamic logic gate including:
a second precharge transistor to precharge a second dynamic node during a second precharge period; and
a second logic block to conditionally discharge said second dynamic node during a second evaluation period following said second precharge period based on a voltage level on said static output node of said static inverter; and
a bias circuit to apply a non-zero bias voltage to said virtual ground node of said static inverter during said second evaluation period.

22. The dynamic logic circuit claimed in claim 21, wherein:
said static inverter couples said bias voltage applied to said virtual ground node by said bias circuit to said static output node when a logic high data value is present on said first dynamic node.

23. The dynamic logic circuit claimed in claim 2 1, wherein:
said bias circuit includes a bootstrap capacitor connected to said virtual ground node of said static inverter, said bootstrap capacitor to generate, by bootstrapping action, a small negative bias voltage on said virtual ground node in response to a clock signal.

24. The dynamic logic circuit claimed in claim 23, wherein:
said bias circuit includes a ground transistor connected to said virtual ground node of said static inverter, said ground transistor to controllably couple said virtual ground node to a ground terminal in response to said clock signal.

25. The dynamic logic circuit claimed in claim 24, wherein:
said ground transistor receives said clock signal at an input terminal thereof, wherein said bootstrap capacitor is connected between said input terminal of said ground transistor and said virtual ground node.

26. The dynamic logic circuit claimed in claim 21, wherein:
said non-zero bias voltage is a small negative voltage.

27. The dynamic logic circuit claimed in claim 21, wherein:
said second logic block includes a wide high fan-in logic structure.

28. The dynamic logic circuit claimed in claim 21, wherein:
said non-zero bias voltage is different from voltages representative of data on said static output node.
